(19) United States
(12) Patent Application Publication
(10) Pub. No.: US 2005/0138512 A1
(43) Pub. Date: Jun. 23, 2005

(54) Semiconductor integrated circuit

(75) Inventors: Kohtaro Inuzuka, Tokyo (JP); Junichi Tamura, Tokyo (JP); Osamu Endoh, Tokyo (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 10/833,999

(22) Filed: Apr. 29, 2004

(30) Foreign Application Priority Data
Dec. 1, 2003 (JP) 2003-401411

(51) Int. Cl. H04N 7/01; H04N 11/20; G01R 31/28

(52) U.S. Cl. 714/727

(57) ABSTRACT

A semiconductor integrated circuit has a plurality of signal paths and a plurality of scan separation circuits. Each scan separation circuit is provided on each signal path. Each scan separation includes a first selector and a second selector. The semiconductor integrated circuit also includes a first circuit block and a second circuit block. The first selector switches between a signal from the first circuit block and an output signal from a flip-flop provided in the scan separation circuit, and supplies the selected signal to the second circuit block. The selected signal is also supplied to the second selector. The second selector selects the signal from the first selector or a signal from outside (or a test signal supplied from an earlier-stage scan separation circuit). The output of the second selector is connected to a flip-flop. The test signal held by the flip-flop is supplied to the first selector and to a subsequent-stage scan separation circuit. During a test, signal paths between the first and second circuit blocks can be tested because the signal from the first circuit block is supplied to and held in the flip-flop via the first and second selectors.

### BACKGROUND OF THE INVENTION

1. Field of the Invention

The present invention relates to a semiconductor integrated circuit with a scan test function.

2. Description of the Related Art

Large-scale semiconductor integrated circuits (called ‘LSIs’ herein below) are often provided with a plurality of functions and/or complicated functions. These LSIs have a test circuit that includes a scan path and a scan path register. The test circuit is used to find defects in the LSI during fabrication of the LSI. One of such LSIs is disclosed in Japanese Patent Kokai (Laid Open Publication) No. 2002-296323.

FIG. 2 of the accompanying drawings illustrates a schematic configuration of an LSI having scan path registers.

This LSI includes an input-side combination circuit 1A, which is supplied with input data DI₁ to DIₓ from an input terminal and generates intermediate signals SA₁ to SAₘ, an intermediate combination circuit 1B, which is supplied with intermediate signals S2₁ to S2ₘ and issues intermediate signals SB₁ to SBₙ, and an output-side combination circuit 1C, which is supplied with intermediate signals S3₁ to S3ₙ and issues output data DO₁ to DO_{y} to an output terminal. A plurality of signal wires (m signal wires) extend between the combination circuits 1A and 1B, and scan path registers (SPR) 2-1 to 2-m are provided on the m signal wires respectively. Likewise, n signal wires extend between the combination circuits 1B and 1C, and scan path registers 3-1 to 3-n are provided on the n signal wires respectively.

All the scan path registers 2-1 to 2-m and 3-1 to 3-n have the same constitution. Each scan path register includes a selector for selecting a first signal or a second signal and a flip-flop (hereinafter referred to as ‘FF’) that holds and releases the signal selected by the selector in accordance with a clock signal. Each selector has first and second inputs.

The first input of the selector of the scan path register 2-1 is supplied with the intermediate signal SA₁ from the combination circuit 1A. The second input of the selector of the scan path register 2-1 is connected to a scan input terminal and is supplied with the signal Sin. The signal produced by the FF of the scan path register 2-1 is supplied to the combination circuit 1B as the intermediate signal S2, and is supplied to the second input of the selector of the subsequent (or downstream) scan path register 2-2 via a scan path.

In a similar manner, the first input of the selector of the scan path register 2-i (that is, i=2 to m) is supplied with the intermediate signal SAi from the combination circuit 1A and the second input of the selector is supplied with the intermediate signal S2ᵢ₋₁, which is produced by the FF of an upstream scan path register 2-(i-1).

The first input of the selector of the scan path register 3-1 is supplied with the intermediate signal SB₁ from the combination circuit 1B, and the second input of the selector is supplied with the intermediate signal S2ₘ from the FF of the scan path register 2-m. Likewise, the first input of the selector of the scan path register 3-j (where j=2 to n) is supplied with the intermediate signal SBⱼ from the combination circuit 1B, while the second input of the selector is supplied with the intermediate signal S2ⱼ₋₁, which is generated by the FF of the scan path register 3-(j-1).

The output of the FF of the scan path register 3-n is connected to the scan output terminal such that the signal Sout is issued.

In an LSI that includes such scan path registers, a fabrication test is performed by means of the following procedure using the scan path registers incorporated beforehand.

(1) Serial Input Operation

All the selectors of the scan path registers 2-1 to 2-m and 3-1 to 3-n are switched to the respective second inputs by means of a control signal (not shown). As a result, all of the scan path registers 2-1 to 2-m and 3-1 to 3-n are vertically connected to form an m+n stage shift register. A common clock signal is supplied to the FF of each of the scan path registers 2-1 to 2-m and 3-1 to 3-n and a test-pattern signal is inputted to each of the scan path registers 2-1 to 2-m and 3-1 to 3-n in series from the scan input terminal Sin in sync with the clock signal. The test pattern is thus held in each of the scan path registers 2-1 to 2-m and 3-1 to 3-n.

(2) Parallel Operation

The test pattern is then supplied to the combination circuits 1B and 1C as a test signal. Meanwhile, the test pattern is supplied to the combination circuit 1A in parallel as the input data DI₁ to DIₓ from the input terminal. Subsequently, signals corresponding to the inputted test pattern are issued in parallel at the respective outputs of the combination circuits 1A, 1B and 1C.

At this time, all of the selectors of the scan path registers 2-1 to 2-m and 3-1 to 3-n are switched to the respective first inputs so that the signals from the selectors are supplied to the inputs of the FFs of the corresponding scan path registers 2-1 to 2-m and 3-1 to 3-n respectively. Next, by supplying a common clock signal to the FFs, signals issued in parallel by the combination circuits 1A and 1B are held in the corresponding FFs. Meanwhile, the output signals of the combination circuit 1C are issued in parallel from the output terminals as the output data DO₁ to DO_{y}.

(3) Serial Output Operation

After the signals issued in parallel by the combination circuits 1A and 1B are held in the corresponding FFs, the selectors of the scan path registers 2-1 to 2-m and 3-1 to 3-n are switched back to the respective second inputs to constitute an m+n stage shift register. A common clock signal is supplied to the FF of each of the scan path registers 2-1 to 2-m and 3-1 to 3-n. The data held in the FFs of the scan path registers 2-1 to 2-m and 3-1 to 3-n are thus issued in series via the scan output terminal Sout in sync with the clock signal.

(4) Comparative Judgment Operation

Based on circuit constitution information of the combination circuits 1A, 1B and 1C, expectation values for the output data to be generated in response to a predetermined test pattern are compared with the data actually generated in series by the serial output operation (3) and the output data DO₁ to DO_{y} of the parallel operation (2). If the actually generated data match the expectation values, the LSI's function with respect to the test pattern is judged as normal. A plurality of test patterns is prepared in accordance with the functions targeted for testing, and, when the actual data match the expectation values for all the test patterns, the whole LSI is judged as normal.

In order to test the functions of the LSI by using this test circuitry, specific circuit constitution information such as a netlist must be used with respect to the combination circuits 1A, 1B, and 1C beforehand and the test patterns corresponding with a variety of function tests must be prepared together with expectation values for the respective test patterns.

However, when a company X fabricates an LSI that incorporates a certain combination circuit upon receiving a license from another company Y, the company X is sometimes unable to obtain specific circuit constitution information of this combination circuit. In this case, a scan separation block is used in order to test the combination circuit and another combination circuit separately.

FIG. 3 of the accompanying drawings shows a schematic configuration of an LSI that includes a conventional scan separation block.

This LSI includes circuit blocks 10A and 10B, and a scan separation block that is constituted by a plurality of scan separation circuits 20-1 to 20-n connected between the circuit blocks 10A and 10B. The scan separation circuits 20-1 to 20-n are provided for the signals SA1 to SAn, respectively. The scan separation circuits 20-1 to 20-n all have the same constitution. Each scan separation circuit includes three selectors 21, 22, and 23 and a single FF 24. Each selector has two input terminals A and B, and a single output terminal. The FF 24 has an input terminal D and an output terminal.

In the scan separation circuit 20-1, the signal SA₁ from the circuit block 10A is supplied to the input terminal A of the selector 21 and the input terminal A of the selector 22. The signal S2₁ for the circuit block 10B is issued from the output terminal of the selector 21. The output terminal of the selector 22 is connected to the input terminal B of the selector 23, and a serial signal Sin from a scan input terminal (not shown) is supplied to the input terminal A of the selector 23. The output terminal of the selector 23 is connected to the input terminal D of the FF 24. The output terminal of the FF 24 is connected to the input terminal B of the selector 21 and the input terminal B of the selector 22. The output terminal of the FF 24 is also connected to the input terminal A of the selector 23 of the subsequent-stage scan separation circuit 20-2 so that a serial signal is supplied to the input terminal A of the selector 23 of the downstream scan separation circuit 20-2.

The output terminal of the FF 24 in the final-stage scan separation circuit 20-n is connected to the input terminals B of the selectors 21 and 22 and to an external device. The output signal from the FF 24 is therefore issued to the external device as a serial signal Sout from the scan output terminal of the LSI.

The LSI that includes this type of scan separation block performs the normal operation and the fabrication test. In the normal operation, each selector 21 is switched to the input terminal A. In the fabrication test, the following is conducted.

(1) Test for Circuit Block 10A

A test pattern is supplied from the parallel input terminals or scan path registers, as described in connection with FIG. 2, to the input (not shown) of the circuit block 10A. The selectors 22 and 23 of each of the scan separation circuits 20-1 to 20-n are switched to the input terminals A and B respectively. As a result, the signals SA1 to SAn, which are generated by the circuit block 10A, are supplied to the input terminals D of the FFs 24 of the scan separation circuits 20-1 to 20-n, respectively. By supplying a common clock signal to all the FFs 24, the signals SA1 to SAn, which are generated in parallel from the circuit block 10A, are held in the corresponding FFs 24.

Next, the selector 23 of each of the scan separation circuits 20-1 to 20-n is switched to the input terminal A. As a result, the FFs 24 of the scan separation circuits 20-1 to 20-n are vertically connected to form an n-stage shift register. A common clock signal is then supplied to the FFs 24 of the scan separation circuits 20-1 to 20-n. Therefore, the data held in the FFs 24 are issued as a serial signal Sout from the scan output terminal in sync with the clock signal.

It is then determined whether the combination circuit 11A is functioning properly by comparing expectation values for the output data to be issued by the circuit block 10A in response to the test pattern, with the actually issued data (i.e., the serial signal Sout).

(2) Test for Circuit Block 10B

The selector 23 in each of the scan separation circuits 20-1 to 20-n is switched to the input terminal A. As a result, the FFs 24 of the scan separation circuits 20-1 to 20-n are vertically connected to form an n-stage shift register. A common clock signal is then supplied to the FFs 24 of the scan separation circuits 20-1 to 20-n and the test-pattern serial signal Sin is inputted from the scan input terminal in sync with the clock signal. As a result, the test patterns are held in the FFs 24 of the scan separation circuits 20-1 to 20-n.

Next, the selectors 21, 22, and 23 in each of the scan separation circuits 20-1 to 20-n are switched to the input terminals B, respectively. As a result, the test patterns held in the FFs 24 are supplied in parallel to the input side of the circuit block 10B.

The signals that are generated in parallel from the output side (not shown) of the circuit block 10B that correspond with the supplied test patterns are read by the parallel output terminals or scan path registers, as described in connection with FIG. 2. It is then determined whether the circuit block 10B is functioning properly by comparing expectation values for the output data to be generated by the circuit block 10B in response to the test pattern with the actually generated data.

In the conventional test performed on the circuit blocks 10A and 10B in the LSI that includes the scan separation circuits 20, a test for the signal path that passes through the input terminal A of the selector 21 in each scan separation circuit 20 is not performed. Hence, the test on the circuit blocks 10A and 10B is unable to detect a fault in the signal path passing through the input terminal A of the selector 21 in the scan separation circuit 20. Therefore, even if the LSI is judged as normal in the test, the LSI sometimes malfunctions. This malfunctioning is often found after the LSI is incorporated in another device.

### SUMMARY OF THE INVENTION

According to one aspect of the present invention, there is provided a semiconductor integrated circuit that includes a first circuit block, a second circuit block, and a scan separation block provided between the first and second circuit blocks. The scan separation block passes a signal between the first and second circuit blocks during normal operation, and separates the first and second circuit blocks from each other during a test operation. The scan separation block includes at least one first scan separation circuit. Each first scan separation circuit has a first holding circuit for holding a first test signal in sync with a clock and a first selector for selecting either a second signal issued by the first circuit block or the first test signal issued by the first holding circuit. The first selector is connected between the second circuit block and the first holding circuit. An output of the first selector is also inputted to the first holding circuit.

The scan separation circuit of the LSI has the holding circuit for holding a signal that is selected by the selector and then issued to another circuit block. The signal path from one circuit block to the other circuit block can therefore be tested by means of a scan test.

Preferably, the first and second circuit blocks are connected to each other by a plurality of signal wires. Preferably, one scan separation circuit is provided on each signal wire. The scan separation circuits may be connected to form a multi-stage structure.

The scan separation block may include at least one second scan separation circuit. Each second scan separation circuit may include a second selector and a second holding circuit. The second selector may select either a test signal supplied by an external input terminal (or the test signal supplied from the earlier-stage scan separation circuit) or the signal selected by the first selector. The second holding circuit may hold the output signal of the second selector in accordance with a clock signal and supply this output signal to the first selector as the test signal. The second holding circuit may also issue the test signal to the external output terminal or to the second selector of the subsequent-stage scan separation circuit.

Other objects, aspects and advantages of the present invention will become apparent to those skilled in the art to which the present invention pertains from the following detailed description and appended claims when read and understood in conjunction with the accompanying drawings.

### BRIEF DESCRIPTION OF THE DRAWINGS

FIG. 1 illustrates a schematic configuration of an LSI that includes a scan separation block according to an embodiment of the present invention;

FIG. 2 illustrates a schematic configuration of an LSI that includes one scan path register; and

FIG. 3 illustrates a schematic configuration of an LSI that includes a conventional scan separation block.

### DETAILED DESCRIPTION OF THE INVENTION

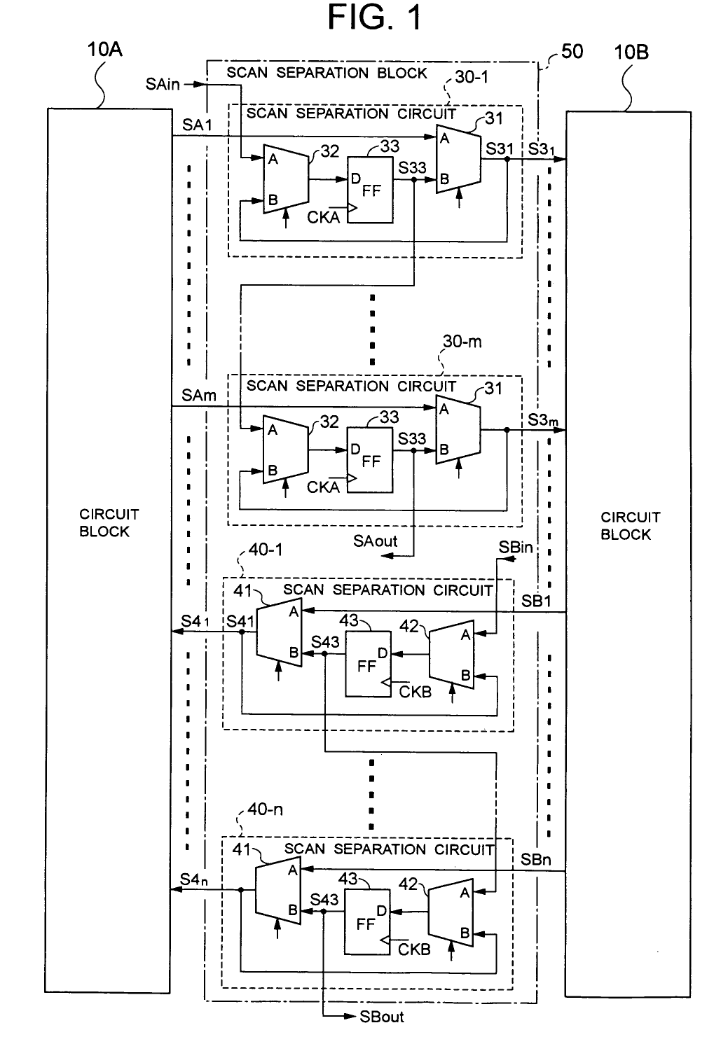

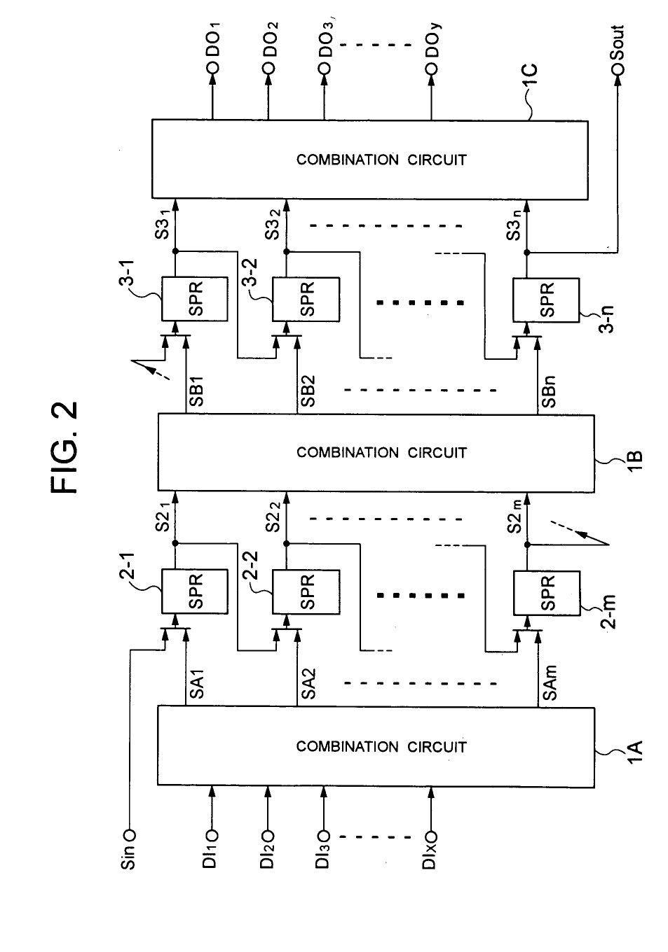

Referring to FIG. 1, an LSI having a scan separation block according to an embodiment of the present invention will be described. Similar reference numerals and symbols are used in FIGS. 1 to 3.

This LSI includes circuit blocks 10A and 10B, and a scan separation block 50 that connects the circuit blocks 10A and 10B. The scan separation block 50 is constituted by a first group of scan separation circuits 30-1 to 30-m and a second group of scan separation circuits 40-1 to 40-n. The scan separation circuits 30-1 and 30-m are respectively provided for the signals SA1 to SAm that are issued to the circuit block 10B from the circuit block 10A. The scan separation circuits 40-1 to 40-n are respectively provided for the signals SB1 to SBn that are issued to the circuit block 10A from the circuit block 10B.

The scan separation circuits 30-1 to 30-m have the same constitution. Each scan separation circuit includes two selectors 31 and 32 and one FF 33. Each selector has an input terminal A and an input terminal B.

In the scan separation circuit 30-1, the signal SA₁ from the circuit block 10A is supplied to the input terminal A of the selector 31 and the signal S3₁ for the circuit block 10B is issued from the output terminal of the selector 31. The signal S3₁ is also supplied to the input terminal B of the selector 32 and the serial signal SAin from the scan input terminal (SAin) is supplied to the input terminal A of the selector 32. The output terminal of the selector 32 is connected to the input terminal D of the FF 33. The output terminal of the FF 33 is connected to the input terminal B of the selector 31 and to the input terminal A of the selector 32 of the subsequent-stage scan separation circuit 30-2. A serial signal is introduced to the input terminal A of the selector 32 of the downstream scan separation circuit 30-2 from the FF 33 of the scan separation circuit 30-1.

The output terminal of the FF 33 in the final-stage scan separation circuit 30-m is connected to the input terminal B of the selector 31 and is connected to the scan output terminal such that a serial signal SAout is issued to the scan output terminal.

Each of the scan separation circuits 40-1 to 40-n has a similar constitution to the scan separation circuit 30 and includes two selectors 41 and 42 and one FF 43. These scan separation circuits 40-1 to 40-n are also connected vertically in the same manner as the scan separation circuits 30-1 to 30-m, such that a serial signal SBin from the scan input terminal is supplied to the initial-stage scan separation circuit 40-1, and the final-stage scan separation circuit 40-n is connected to the scan output terminal such that a serial signal SBout is issued to the scan output terminal.

Next, the operation of the LSI that includes the scan separation block 50 will be described.

(1) Normal Operation

The selector 31 of each of the scan separation circuits 30-1 to 30-m is switched to the input terminal A, and the selector 41 of each of the scan separation circuits 40-1 to 40-n is switched to the input terminal A. As a result, the signals SA1 to SAm generated by the circuit block 10A are supplied to the circuit block 10B as the signals S3₁ to S3m respectively after passing via the selectors 31 of the scan separation circuits 30-1 to 30-m respectively. The signals SB1 to SBn generated by the circuit block 10B are supplied to the circuit block 10A as the signals S4₁ to S4n respectively after passing via the selectors 41 of the scan separation circuits 40-1 to 40-n respectively.

(2) Test for Circuit Block 10A

A test pattern is supplied to the input side (not shown) of the circuit block 10A.

The selector 42 of each of the scan separation circuits 40-1 to 40-n is switched to the input terminal A. As a result, the FFs 43 of the scan separation circuits 40-1 to 40-n are vertically connected to form an n-stage shift register. A common clock signal CKB is then supplied to the FFs 43 of the scan separation circuits 40-1 to 40-n. The test-pattern serial signal SBin from the scan input terminal is introduced to each of the scan separation circuits 40-1 and 40-n in sync with this clock signal CKB. As a result, the test pattern is held in the FF 43 of each of the scan separation circuits 40-1 to 40-n.

Next, the selectors 41 and 42 in each of the scan separation circuits 40-1 to 40-n are switched to the respective input terminals B. As a result, the test patterns held in the FFs 43 are supplied in parallel to the circuit block 10A via the respective selectors 41.

Thus, the circuit block 10A performs all possible operations based on signals supplied to the input side of the circuit block 10A, and generates the signals SA1 to SAm as well as an output signal from the output terminal (not shown).

Thereafter, the selectors 31 and 32 in each of the scan separation circuits 30-1 to 30-m are switched to the input terminals A and B respectively. As a result, the signals SA1 to SAm generated by the circuit block 10A are supplied to the input terminals D of the FFs 33 via the selectors 31 and 32 of the scan separation circuits 30-1 to 30-m, respectively. By supplying a common clock signal CKA to the FF 33 in the scan separation circuits 30-1 to 30-m, the signals SA1 to SAm, which are generated in parallel by the circuit block 10A, are held in the FFs 33 of the corresponding scan separation circuits 30-1 to 30-m respectively.

Next, the selector 32 in each of the scan separation circuits 30-1 to 30-m is switched to the input terminal A. The FFs 33 of the scan separation circuits 30-1 to 30-m are vertically connected to form an m-stage shift register. A common clock signal CKA is then supplied to the FFs 33 of the scan separation circuits 30-1 to 30-m. As a result, the data held in the FFs 33 are issued from the scan output terminal as a serial signal SAout in sync with the clock signal CKA.

It is determined whether the circuit block 10A is functioning properly by comparing expectation values for the output data to be generated by the circuit block 10A in response to the test pattern with the data that is actually generated as the serial signal SAout.

(3) Test for Circuit Block 10B

The circuit block 10B has symmetry with the circuit block 10A. Therefore, a process that is generally the reverse of the test (2) is performed for the circuit block 10B. The test pattern (i.e., the serial signal SAin) is introduced to the circuit block 10B from the scan separation circuits 30-1 to 30-m. It can be determined whether the circuit block 10B is functioning properly by reading the generated signals SB1 to SBn as the serial signal SBout by means of the scan separation circuits 40-1 to 40-n.

In this embodiment, each scan separation circuit 30-i (40-j) includes the selector 31 (41), which switches between the signal SAᵢ (SBⱼ) generated by the circuit block 10A (10B) and a test signal and then supplies the selected signal to the circuit block 10B (10A). Each scan separation circuit 30-i (40-j) also includes the selector 32 (42), which switches between the output signal of the selector 31 (41) and a test serial signal. Each scan separation circuit 30-i (40-J) also includes the FF 33 (43), which holds the signal issued by the selector 32 (42) before supplying this signal to the selector 31 (41) and outputting this signal as the test serial signal. As a result, the test for the circuit blocks 10A and 10B can check the signals passing through all the signal paths in the LSI. Thus, the LSI does not malfunction after the LSI is mounted in the device.

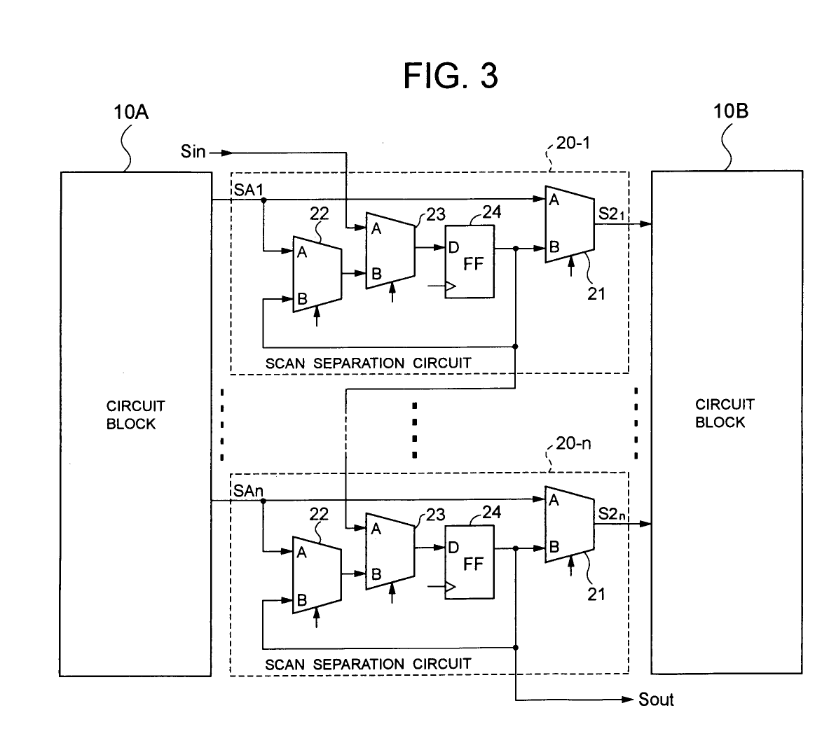

Each of the scan separation circuits 30 and 40 in FIG. 1 has one less selector than the scan separation circuit 20 in FIG. 3. Therefore, it is possible to reduce the circuit pattern area by approximately 10%.

The scan separation circuit 30 (or 40) with this constitution is applicable to a scan separation circuit with an extended function that masks a portion of the test pattern before issuing the test pattern to a circuit block in parallel.

In addition to general LSIs, practical applications of the present invention include integrated circuits (ASIC) conceived for a specific purpose.

This application is based on a Japanese Patent Application No. 2003-401411 filed on Dec. 1, 2003, and the entire disclosure thereof is incorporated herein by reference.

1. A semiconductor integrated circuit comprising:
a first circuit block;
a second circuit block;
a scan separation block provided between the first and second circuit blocks for passing a signal between the first and second circuit blocks during normal operation and for separating the first and second circuit blocks from each other during a test operation;
wherein the scan separation block includes at least one first scan separation circuit, and each of the at least one first scan separation circuit has a first holding circuit for holding a first test signal in sync with a clock and a first selector for selecting either a second signal issued by the first circuit block or the first test signal issued by the first holding circuit, the first selector being connected between the second circuit block and the first holding circuit, and an output of the first selector being also inputted to the first holding circuit.

2. The semiconductor integrated circuit according to claim 1, wherein the scan separation block further includes at least one second scan separation circuit, and each of the at least one second scan separation circuit has a second holding circuit for holding a third test signal in sync with the clock and a second selector for selecting either a fourth signal issued by the second circuit block or the third test signal issued by the second holding circuit, the second selector being connected between the first circuit block and the second holding circuit and an output of the second selector being also inputted to the second holding circuit.

3. The semiconductor integrated circuit according to claim 2, wherein the scan separation block includes a plurality of said first scan separation circuits and a plurality of said second scan separation circuits.

4. The semiconductor integrated circuit according to claim 3, wherein the plurality of said first scan separation circuits are connected in multiple stages, and the first test signal of one of the first scan separation circuits is supplied to a subsequent-stage said first scan separation circuit.

5. The semiconductor integrated circuit according to claim 3, wherein the plurality of said second scan separation circuits are connected in multiple stages, and the third test signal of one of the second scan separation circuits is supplied to a subsequent-stage said second scan separation circuit.

6. The semiconductor integrated circuit according to claim 4, wherein each of the first scan separation circuits includes a third selector for selecting the output of the first selector of the first scan separation circuit concerned or the first test signal issued by the earlier-stage said first scan separation circuit, and for supplying the selected signal to the first holding circuit of the first scan separation circuit concerned.

7. The semiconductor integrated circuit according to claim 5, wherein each of the second scan separation circuits includes a fourth selector for selecting the output of the second selector of the second scan separation circuit concerned and the third test signal issued by the earlier-stage said second scan separation circuit, and for supplying the selected signal to the second holding circuit of the second scan separation circuit concerned.

8. The semiconductor integrated circuit according to claim 6, wherein only selectors included in each of said first scan separation circuits are the first and third selectors.

9. The semiconductor integrated circuit according to claim 7, wherein only selectors included in each of said second scan separation circuits are the second and fourth selectors.

10. The semiconductor integrated circuit according to claim 1, wherein the first holding circuit is a flip-flop.

11. The semiconductor integrated circuit according to claim 2, wherein the second holding circuit is a flip-flop.
